(19) United States
(12) Patent Application Publication
(10) Pub. No.: US 2015/0062843 A1
(43) Pub. Date: Mar. 5, 2015

(54) SEMICONDUCTOR DEVICE AND ELECTRONIC APPARATUS

(71) Applicant: KABUSHIKI KAISHA TOSHIBA, Minato-ku (JP)

(72) Inventors: Teppei HIGASHITSUJI, Fujisawa-shi (JP); Toshifumi MINAMI, Yokohama-shi (JP); Hideyuki KAMATA, Kawasaki-shi (JP); Atsuhiro SATO, Tokyo (JP); Keisuke YONEHAMA, Yokohama-shi (JP)

(73) Assignee: KABUSHIKI KAISHA TOSHIBA, Minato-ku (JP)

(21) Appl. No.: 14/206,205

(22) Filed: Mar. 12, 2014

Related U.S. Application Data
(60) Provisional application No. 61/873,174, filed on Sep. 3, 2013.

(51) Int. Cl. H01L 27/115; H05K 7/14; H01L 23/535

(52) U.S. Cl. CPC H01L 27/11578; H01L 23/535; H05K 7/14
USPC 361/752; 257/774

(57) ABSTRACT

According to one embodiment, a semiconductor device includes a cell portion and a peripheral portion, including: a substrate, a first insulating layer disposed on the substrate, a first conductive layer disposed on the first insulating layer, a second insulating layer disposed on the first conductive layer, and a second conductive layer disposed on the second insulating layer.

### CROSS REFERENCE TO RELATED APPLICATIONS

This application claims the benefit of U.S. Provisional Application No. 61/873,174, filed Sep. 3, 2013, the entire contents of which are incorporated herein by reference.

### FIELD

Embodiments described herein relate generally to a semiconductor device and an electronic apparatus.

### BACKGROUND

A semiconductor device having a substrate in which a transistor is provided and a lamination structure laminated on the substrate is provided.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exploded perspective view illustrating a portion of a semiconductor device according to a first embodiment;

FIG. 2 is a plan view illustrating a semiconductor part of FIG. 1;

FIG. 3 is a cross-sectional diagram illustrating the semiconductor part taken along line F3-F3 of FIG. 2;

FIG. 4 is a cross-sectional diagram illustrating a peripheral portion of the semiconductor part of FIG. 3;

FIG. 5 is a cross-sectional diagram illustrating the peripheral portion of the semiconductor part taken along line F5-F5 of FIG. 4;

FIG. 6 is a cross-sectional diagram illustrating the peripheral portion of the semiconductor part of FIG. 4;

FIG. 7 is a cross-sectional diagram illustrating the peripheral portion of the semiconductor part taken line F6-F6 of FIG. 6;

FIG. 8 is a cross-sectional diagram illustrating the first half portion of an example of a method of manufacturing the semiconductor part of FIG. 3;

FIG. 9 is a cross-sectional diagram illustrating the second half portion of the example of the method of manufacturing the semiconductor part of FIG. 3;

FIG. 10 is a cross-sectional diagram illustrating an example of a method of manufacturing the semiconductor part of FIG. 3;

FIG. 11 is a cross-sectional diagram illustrating a peripheral portion of a semiconductor part according to a second embodiment;

FIG. 12 is a cross-sectional diagram illustrating the peripheral portion of the semiconductor part taken along line F12-F12 of FIG. 11;

FIG. 13 is a cross-sectional diagram illustrating a peripheral portion of a semiconductor part according to a third embodiment;

FIG. 14 is a cross-sectional diagram illustrating the peripheral portion of the semiconductor part taken along line F14-F14 of FIG. 13;

FIG. 15 is a perspective view illustrating an electronic apparatus according to a fourth embodiment; and

FIG. 16 is a perspective view illustrating a circuit board of FIG. 15.

### DETAILED DESCRIPTION

Various embodiments will be described hereinafter with reference to the accompanying drawings.

In general, according to one embodiment, a semiconductor device is configured to include a cell portion and a peripheral portion, including: a substrate, a first insulating layer disposed on the substrate, a first conductive layer disposed on the first insulating layer, a second insulating layer disposed on the first conductive layer, a second conductive layer disposed on the second insulating layer, a first wiring layer disposed between the first insulating layer and the substrate, a second wiring layer disposed above the second conductive layer, a third insulating film disposed in the peripheral portion, the third insulating film being extending in a first direction perpendicular to the substrate, and a contact disposed in an area surrounded by the third insulating film, the contact being connected to the first wiring layer and the second wiring layer.

In the specification, plural expressions are used for some components. These expressions are exemplarily used, and thus, other expressions can be used for the component. In addition, components which are not described with plural expressions may also be described with other expressions.

In addition, figures of the drawings are schematically illustrated, and thus, relationships between thicknesses and surface dimensions and a ratio of thicknesses of layers may be different from those of an actual case. In addition, between the figures, portions having different relations or ratios of dimensions may be included.

### First Embodiment

FIGS. 1 to 10 illustrate a semiconductor device 1 according to a first embodiment. The semiconductor device 1 is, for example, a semiconductor storage device and a non-volatile memory. An example of the semiconductor device 1 is an SD memory card (trademark). In addition, the semiconductor device 1 may be other semiconductor storage devices such as a USB memory, a Compact Flash (trademark), or a volatile memory or may be a semiconductor device other than storage devices.

FIG. 1 is an exploded perspective view illustrating a portion of the semiconductor device 1 according to the first embodiment. As illustrated in FIG. 1, the semiconductor device 1 according to the embodiment is configured to include a case 2, a circuit board 3, a controller 4, and a semiconductor part 5. The case 2 (i.e., a case, an outer frame, a protective portion) has, for example, a flat box shape corresponding to the standards of the SD memory card. The case 2 is divided into an upper case portion 2a and a lower case portion 2b.

The circuit board 3 (i.e., a printed board) is accommodated in the case 2. The controller 4 and the semiconductor part 5 are mounted on the circuit board 3 to be connected to the circuit board 3. The controller 4 controls the semiconductor part 5 (e.g., access control).

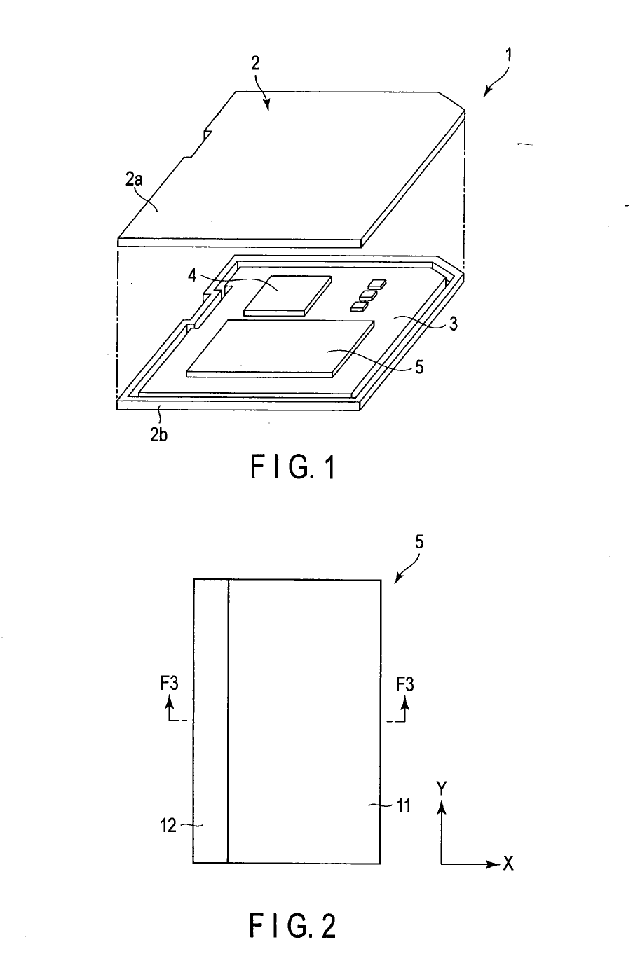

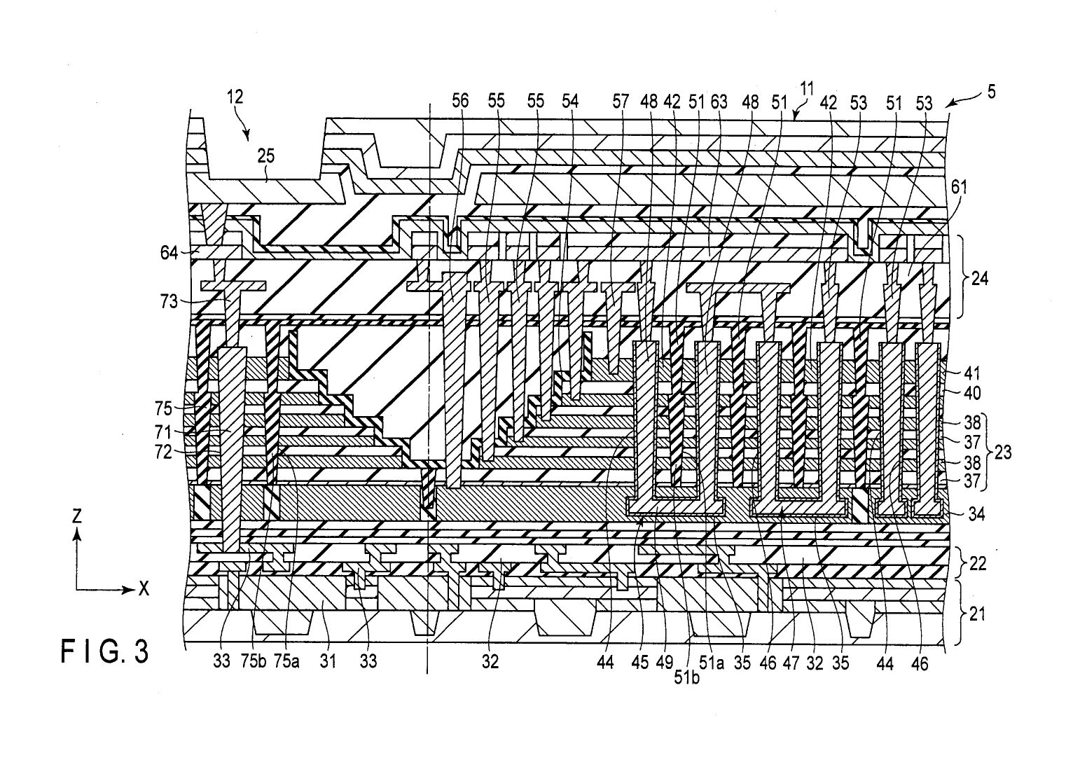

FIGS. 2 and 3 are a plan view and a cross-sectional diagram of the semiconductor part 5. As illustrated in FIGS. 2 and 3, the semiconductor part 5 is a so-called three-dimensional memory and is configured to include a cell portion 11 (e.g., cell area, memory cell area), and a peripheral portion 12 (e.g., peripheral area, peripheral circuit portion).

The cell portion 11 includes a plurality of memory cells which are arranged three-dimensionally (i.e., stereoscopically). The peripheral portion 12 is positioned at an end of the semiconductor part 5 and includes at least a portion of circuits (e.g., peripheral circuits) driving the memory cells.

As illustrated in FIG. 3, the semiconductor part 5 is configured to include a substrate 21, a first wiring layer 22, a lamination structure 23, a second wiring layer 24, and a pad 25. The substrate 21 is a silicon substrate (e.g., silicon wafer), and a transistor 31 (e.g., peripheral transistor) is provided in the substrate 21. The transistor 31 constitutes, for example, a portion of a CMOS (Complementary Metal Oxide Semiconductor) circuit provided on the substrate 21. In addition, in FIG. 3, the transistor 31 is schematically illustrated.

The first wiring layer 22 is provided between the substrate 21 and the lamination structure 23. The first wiring layer 22 is laminated, for example, on substantially the entire surface of the substrate 21. The first wiring layer 22 is configured to include an insulating layer 32 and a metal wiring 33 (i.e., a wiring pattern) provided on the insulating layer 32. The metal wiring 33 is connected to the transistor 31 (e.g., a CMOS circuit) in the substrate 21.

Herein, the X direction, the Y direction, and the Z direction are defined as follows. The X and Y directions are substantially parallel to the surface of the substrate 21. The X direction is directed, for example, from the peripheral portion 12 toward the cell portion 11. The Y direction is substantially perpendicular to the X direction. The Z direction is substantially perpendicular to the X and Y directions and is the thickness direction of the semiconductor part 5. In addition, the Z direction is also the lamination direction of the lamination structure 23.

A conductive layer 34 is provided on the first wiring layer 22. The conductive layer 34 is formed with a conductive material, for example, silicon doped with phosphorus (i.e., phosphorus-doped silicon). The conductive layer 34 becomes a back gate electrode of the cell portion 11. A plurality of connecting holes 35 having a rectangular parallelepiped shape extending in the X or Y direction are formed in the back gate electrode. A thin thermal oxide film is formed on an inner surface of the connecting hole 35.

As illustrated in FIG. 3, the lamination structure 23 (e.g., lamination wiring, lamination structure, memory cell device) is provided on the conductive layer 34. The lamination structure 23 is configured to include a plurality of insulating layers 37 (e.g., insulating films) and a plurality of conductive layers 38 (e.g., conductive films) which are alternately laminated in the Z direction. The insulating layer 37 is formed, for example, with a silicon oxide. In addition, in FIG. 3, the layer number of insulating layers 37 and conductive layers 38 each are four, but it is merely an exemplary number.

The conductive layer 38 is, for example, an electrode film constituting a word line in the cell portion 11. The conductive layer 38 is formed, for example, with a boron doped silicon film made of silicon (i.e., boron doped silicon) into which boron is introduced. The insulating layers 37 and the conductive layers 38 are laminated on substantially the entire area of the substrate 21 over the cell portion 11 and the peripheral portion 12.

An insulating layer 40 formed with, for example, a silicon oxide film is provided on the lamination structure 23. A conductive layer 41 formed with, for example, boron doped silicon is provided on the insulating layer 40. The conductive layer 41 is configured to include a plurality of control electrodes 42 extending in the Z direction in the cell portion 11.

As illustrated in FIG. 3, a plurality of memory holes 44 is provided in the cell portion 11. The memory holes 44 are arranged in a matrix shape in the X and Y directions and penetrate the control electrodes 42, the insulating layer 40, and the lamination structure 23 in the Z direction to reach the both ends of the connecting hole 35 in the back gate electrode (i.e., the conductive layer 34). Therefore, a pair of the memory holes 44 adjacent to each other is configured to communicate with each other through the connecting hole 35 so as to constitute one U-shaped hole 45.

Each memory hole 44 has, for example, a cylindrical shape. Each of the U-shaped holes 45 has a substantially U shape. A memory film 46 is provided on an inner surface of the U-shaped hole 45 (i.e., an inner surface of the memory hole 44). The memory film 46 is configured to include a block insulating film, a charge storage film, and a tunnel insulating film.

The block insulating film is provided on an inner surface of the U-shaped hole 45 (i.e., an inner surface of the memory hole 44). The block insulating film is an insulating film through which no current flows even though a voltage in a driving voltage range of the device is applied to the insulating film. The block insulating film is made of a high dielectric material, for example, a material of which dielectric constant is higher than that of a material for the below-described charge storage film and is formed with, for example, a silicon oxide film.

The charge storage film is provided on the block insulating film and is a film having a charge storing capability. The charge storage film is, for example, a film including electron trap sites and is, for example, a silicon nitride film. The tunnel insulating film is provided on the charge storage film. The tunnel insulating film has an insulating property in general, but when a predetermined voltage in a driving voltage range of the device is applied to the tunnel insulating film, a tunnel current flows through the tunnel insulating film. The tunnel insulating film is formed with, for example, a silicon oxide. The memory film 46 is formed by laminating the block insulating film, the charge storage film, and the tunnel insulating film in this order.

Polysilicon which impurities, for example, phosphorus are introduced into is buried in the U-shaped hole 45, so that a U-shaped filler 47 is formed. The shape of the U-shaped filler 47 is a U-shaped shape reflecting the shape of the U-shaped hole 45. The U-shaped filler 47 is in contact with the tunnel insulating film. The U-shaped filler 47 is configured to include a silicon filler 48 disposed in the memory hole 44 and a connection portion 49 disposed in the connecting hole 35. Therefore, the charge storage film is disposed between a conductor layer 38 of the lamination structure 23 and the silicon filler 48.

In the above-described configuration, a memory cell (e.g., memory cell transistor) is formed at the intersection of each conductor layer 38 and each silicon filler 48. In addition, a selection transistor is formed at the intersection of each control electrode 42 and each silicon filler 48. A memory string is configured between a bit line and a source line so that a plurality of the memory cells (e.g., memory cell transistors) is serially connected to each other and selection transistors are connected to both sides of the memory string.

Accordingly, by controlling potentials of each conductor layer 38 and each silicon filler 48, charges are inserted and extracted between the silicon filler 48 and the charge storage layer of the memory film 46, and thus information can be stored.

As illustrated in FIG. 3, the semiconductor part 5 is configured to include insulating portions 51 extending in the Z direction between a plurality of the memory holes 44 and between a plurality of the control electrodes 42. The insulating portion 51 is configured to include a slit 51a extending in the Z direction and an insulating film 51b (e.g., slit insulating film, interlayer film, insulating portion) buried in the slit 51a. The insulating film 51b is formed with, for example, a silicon oxide film. In addition, the insulating portion 51 may be an air gap which is formed with only the slit 51a.

The insulating portions 51 are provided, so that a plurality of the silicon fillers 48 is insulated from each other and a plurality of the control electrodes 42 is insulated from each other. Plugs 53 are provided just above the control electrodes 42. The plugs 53 are connected to the silicon fillers 48.

As illustrated in FIG. 3, the end of the lamination structure 23 in the cell portion 11 is formed to have a shape of steps in the X direction, and each of the conductive layers 38 arranged in the Z direction constitutes each step. An insulating film 54 formed with, for example, a silicon oxide film is provided on the side surfaces of the lamination structure 23, the insulating layer 40, and the control electrode 42 which are formed to have a shape of steps. The insulating film 54 is formed to have a shape of steps reflecting the shape of the end of the lamination structure 23.

In addition, a plurality of contacts 55 is provided on the step portions of the lamination structure 23. A plurality of the contacts 55 extends in the Z direction to connect the conductive layers 38 of the steps and the below-described second wiring layer 24. In addition, one contact 56 connects the conductive layer 34 which becomes the back gate electrode to the second wiring layer 24. In addition, another contact 57 connects the control electrode 42 to the second wiring layer 24.

As illustrated in FIG. 3, the second wiring layer 24 is provided on the control electrode 42. Namely, the lamination structure 23 or the conductive layer 41 is disposed between the second wiring layer 24 and the first wiring layer 22. The second wiring layer 24 is laminated, for example, on substantially the entire area of the semiconductor part 5. The second wiring layer 24 is configured to include an insulating layer 61 and a plurality of the metal wirings 63, 64, and 65 (i.e., a wiring pattern) which are provided on the insulating layer 61.

The metal wiring 63 is provided in the cell portion 11 and includes source lines or the like. The metal wiring 63 is connected to conductive layer 38 of the lamination structure 23 or the silicon filler 48 through the contact 55, 56, or 57 or the plug 53.

Another metal wiring 64 is provided in the peripheral portion 12 to be connected to the below-described contact 71. A pad 25 is provided on the second wiring layer 24. The pad 25 is exposed to, for example, an external portion of the semiconductor part 5. The metal wiring 64 is connected to the pad 25. The metal wiring 65 will be described later.

Next, the peripheral portion 12 will be described in detail.

As illustrated in FIG. 3, for example, a contact hole 72 (i.e., a through-hole) is provided in the peripheral portion 12. The contact hole 72 penetrates the conductive layer 41, the insulating layer 40, the lamination structure 23, and the conductive layer 34 in the Z direction to reach the first wiring layer 22. The contact hole 72 has, for example, a cylindrical shape which is substantially the same as or substantially similar to the shape of the memory hole 44. The contact hole 72 has a shape which is opened by using the same mask as that for the memory hole 44.

A contact 71 is buried in the contact hole 72. The contact 71 penetrates the conductive layer 41, the insulating layer 40, the lamination structure 23, and the conductive layer 34 in the Z direction to reach the first wiring layer 22. The contact 71 is connected to the metal wiring 33 of the first wiring layer 22.

On the other hand, another contact 73 is provided on the contact 71. The contact 73 extends between the contact 71 and the second wiring layer 24 and is connected to the metal wiring 64 of the second wiring layer 24. The contact 71 connects the first wiring layer 22 and the second wiring layer 24 through the contact 73, so that the pad 25 and the transistor 31 (e.g., a CMOS circuit) in the substrate 21 are connected to each other.

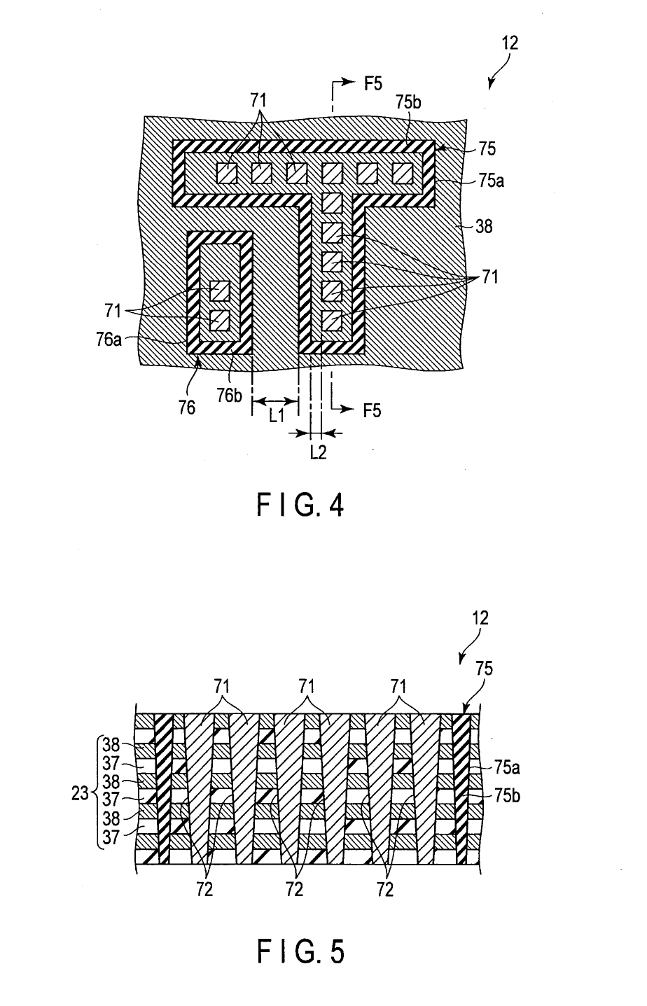

FIG. 4 is a cross-sectional diagram illustrating the peripheral portion 12 of the semiconductor part 5 as viewed from the upper side. FIG. 5 is a cross-sectional diagram illustrating the semiconductor part 5 taken along line F5-F5 of FIG. 4. As illustrated in FIGS. 4 and 5, a plurality of the contact holes 72 and a plurality of contacts 71 are provided.

As illustrated in FIGS. 4 and 5, the semiconductor part 5 is configured to include an insulating portion 75 which surrounds the contacts 71 (or the contact holes 72) in the direction (e.g., the X and Y directions) intersecting the lamination direction of the lamination structure 23 and extends in the Z direction. The insulating portion 75 penetrates at least a portion of the lamination structure 23. The insulating portion 75 is configured to include a slit 75a extending in the Z direction and an insulating film 75b (e.g., a slit insulating film) buried in the slit 75a. The insulating film 75b is formed with, for example, a silicon oxide film. The insulating film 75b is formed in substantially the same process as that for the insulating film 51b in the cell portion 11 (e.g., substantially simultaneously). In addition, the insulating portion 75 may be an air gap which is formed with only the slit 75a.

As illustrated in FIG. 3, the insulating portion 75 penetrates the conductive layer 41, the insulating layer 40, and the lamination structure 23 in the Z direction to reach the conductive layer 34. In addition, as illustrated in FIGS. 4 and 5, the insulating portion 75 integrally surrounds the plurality of contacts 71.

The insulating portion 75 is provided, so that the plurality of contacts 71 disposed at the inner side of the insulating portion 75 are insulated from the conductive layers 38 of the lamination structure 23 disposed at the outer side of the insulating portion 75. On the other hand, the contacts 71 are connected to a plurality of the conductive layers 38 of the lamination structure 23 at the inner side of the insulating portion 75. In addition, the plurality of contacts 71 is connected to each other through a plurality of the conductive layers 38 of the lamination structure 23 at the inner side of the insulating portion 75.

In addition, another insulating portion 76 which surrounds the contacts 71 and extends in the Z direction is provided in the semiconductor part 5. The insulating portion 76 penetrates at least a portion of the lamination structure 23. The insulating portion 76 is configured to include a slit 76a extending in the Z direction and an insulating film 76b (e.g., a slit insulating film) buried in the slit 76a. The insulating film 76b is formed with, for example, a silicon oxide film. The insulating portion 76 may be an air gap which is formed with only the slit 76a.

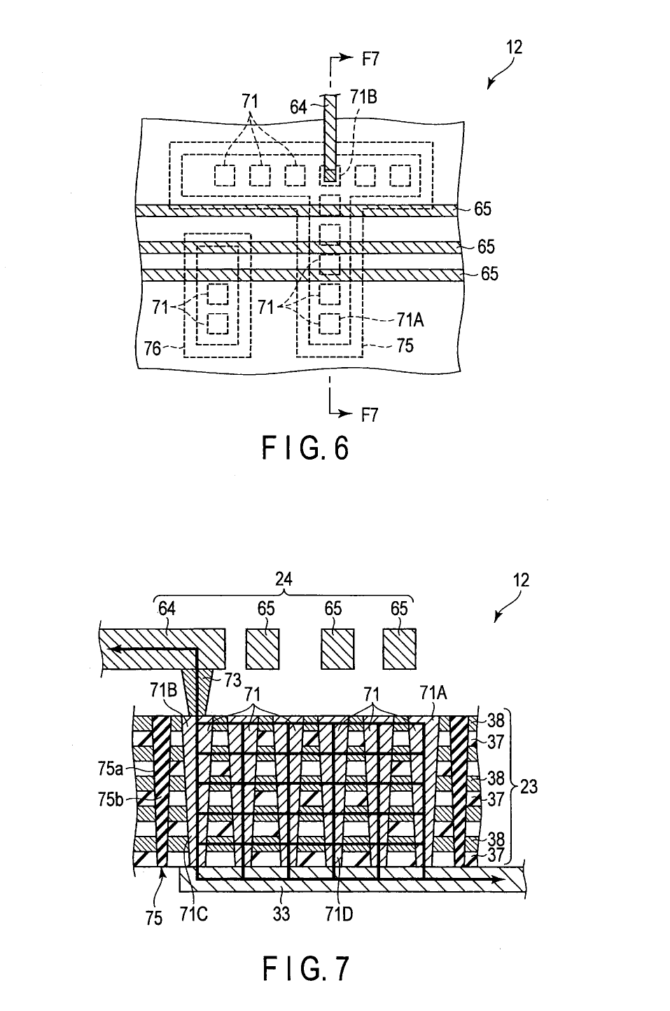

FIGS. 6 and. 7 are formed by adding metal wirings 33, 64, and 65 of the first and second wiring layers 23 and 24 to FIGS. 4 and 5. As illustrated in FIG. 7, the plurality of contacts 71 is configured to include a first contact 71A and a second contact 71B. The first contact 71A is connected to the metal wiring 33 of the first wiring layer 22. The second contact 71B is connected to the metal wiring 64 of the second wiring layer 24.

The first contact 71A and the second contact 71B are connected to each other through a plurality of the conductive layers 38 of the lamination structure 23 at the inner side of the insulating portion 75. Therefore, a conductive path connecting the metal wiring 33 of the first wiring layer 22 and the metal wiring 64 of the second wiring layer 24 through the first contact 71A, the second contact 71B, and the conductive layers 38 is provided.

In addition, in the embodiment, the second contact 71B is directly connected to the metal wiring 33 of the first wiring layer 22. In other words, each of the contacts 71 is connected to the metal wiring 33 of the first wiring layer 22. Therefore, as indicated by solid lines in FIG. 6, mesh-shaped conductive paths are formed by using the metal wiring 33 of the first wiring layer 22, the plurality of contacts 71, and a plurality of the conductive layers 38.

In addition, the “mesh-shaped conductive paths” described herein denote a configuration where the plurality of contacts 71 is connected to the first wiring layer 22 so that current individually flows between the first wiring layer 22 and the plurality of contacts 71, and the current flowing through each of the contacts 71 can flow into adjacent contact 71 through at least one conductive layer 38.

In addition, the “mesh-shaped conductive paths” may be provided between the plurality of contacts 71 and the second wiring layer 24 instead of between the plurality of contacts 71 and the first wiring layer 22. In addition, the “mesh-shaped conductive paths” may be configured to include the plurality of contacts 71 and a plurality of the conductive layers 38 without including the first wiring layer 22 and the second wiring layer 24. In addition, the “mesh-shaped conductive paths” may be configured to include three or more contacts 71 and three or more conductive layers 38.

In addition, in the embodiment, the plurality of contacts 71 includes a first contact 71C and a second contact 71D which are classified according to a point of view different from the above-described point of view. The first contact 71C and the second contact 71D are connected to each other through a plurality of the conductive layers 38 of the lamination structure 23 at the inner side of the insulating portion 75.

As described above, the second wiring layer 24 is configured to include a metal wiring 64 (hereinafter, referred to as a first metal wiring) and a metal wiring 65 (hereinafter, referred to as a second metal wiring). The first metal wiring 64, a projection of the metal wiring overlapping the first contact 71C in the thickness direction (i.e., the Z direction) of the lamination structure 23 and is connected to the first contact 71C. The second metal wiring 65, a projection of the metal wiring overlapping the second contact 71D in the thickness direction (i.e., the Z direction) of the lamination structure 23 and is insulated from the second contact 71D. Namely, the second metal wiring 65 is a wiring pattern provided by using an upper space of the second contact 71D irrespective of potentials of the first and second contacts 71C and 71D.

Next, an example of a method of manufacturing the semiconductor part 5 will be described.

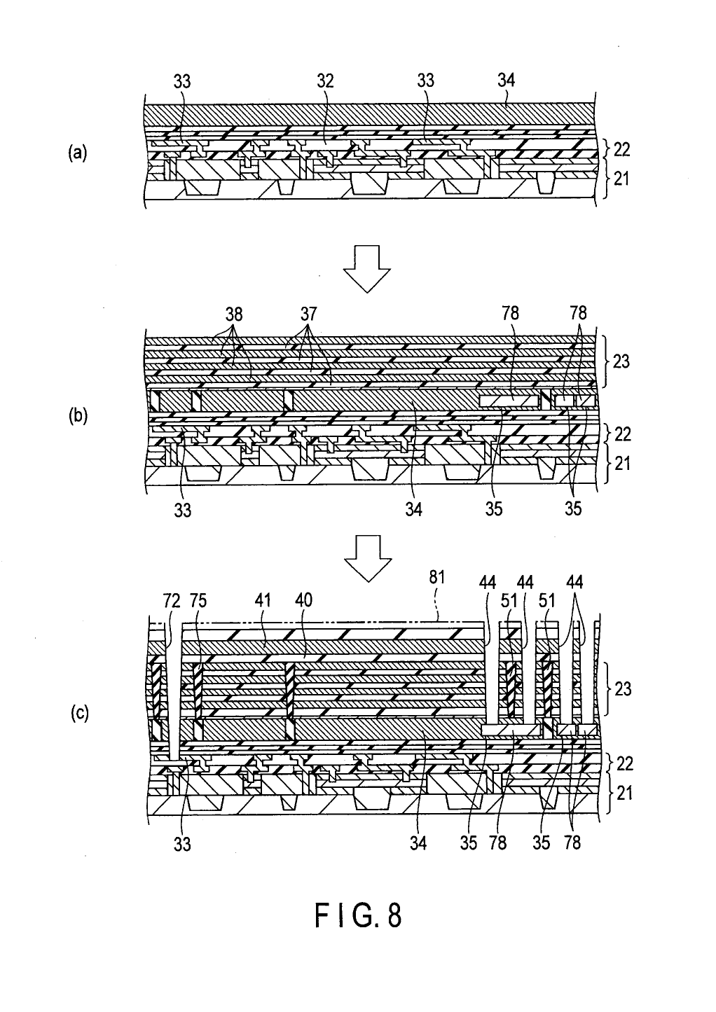

FIG. 8 illustrates a first half portion of the method of manufacturing the semiconductor part 5.

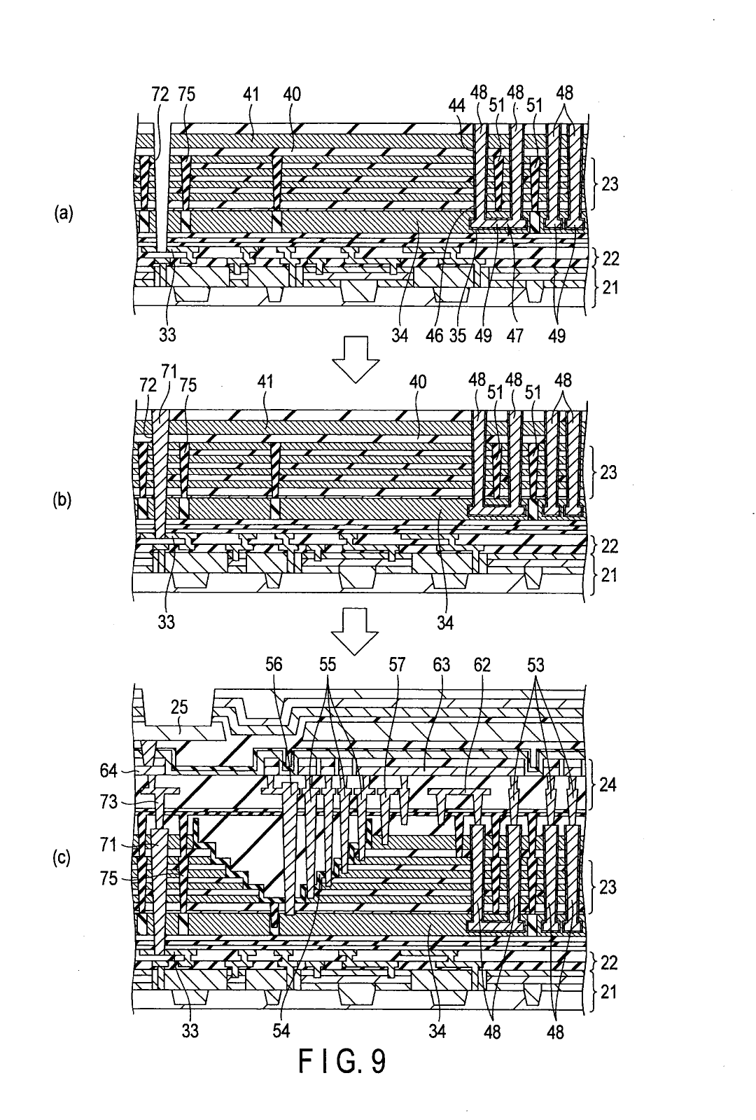

FIG. 9 illustrates a second half portion of the method of manufacturing the semiconductor part 5. As illustrated in (a) of FIG. 8, first, a substrate 21 is prepared, and a first wiring layer 22 and a conductive layer 34 are formed on the substrate 21. As illustrated in (b) of FIG. 8, a connecting hole 35 which becomes a portion of a U-shaped hole 45 is provided in the conductive layer 34. In addition, in this step, the connecting hole 35 is filled with, for example, a sacrificial material 78 which is made of a silicon nitride. The sacrificial material 78 is removed in a following process.

Next, a lamination structure 23 is laminated on the conductive layer 34. The lamination structure 23 is formed by using, for example, a CVD (chemical vapor deposition) method. Next, a portion of an insulating portion 51 (or an insulating film 51b) of the cell portion 11 and a portion of an insulating portion 75 (or an insulating film 75b) of the peripheral portion 12 are formed in the same process substantially simultaneously. Next, an insulating layer 40 and a conductive layer 41 are formed on the lamination structure 23.

Next, as illustrated in (c) of FIG. 8, a plurality of memory holes 44 and a contact hole 72 are provided. Therefore, the memory hole 44 is connected to the connecting hole 35 of the conductive layer 34 to constitute a portion of the U-shaped hole 45.

The memory hole 44 and the contact hole 72 are opened by using, for example, a photolithography method and an etching method. In the embodiment, the memory hole 44 and the contact hole 72 are formed in the same process using the same mask 81 (e.g., a common mask, a resist film) substantially simultaneously.

Next, as illustrated in (a) of FIG. 9, the sacrificial material 78 is removed from the U-shaped hole 45, and a memory film 46 and a U-shaped filler 47 is provided inside the U-shaped hole 45. Therefore, a memory cell is formed at the intersection of the conductive layer 38 and the memory film 46.

Next, as illustrated in (b) of FIG. 9, a contact 71 is provided in the contact hole 72. The contact 71 is made of, for example, tungsten, but the present invention is not limited thereto. After the contact 71 is provided, a planarization process using, for example, a CMP (chemical mechanical polishing) method is performed on the surfaces of the contact 71 and the surface of the silicon filler 48.

As illustrated in (c) of FIG. 9, a remaining portion of the insulating portion 51 (or an insulating film 51b) of the cell portion 11 and a remaining portion of the insulating portion 75 (or an insulating film 75b) of the peripheral portion 12 are formed in the same process substantially simultaneously. Next, contacts 55, 56, 57, and 73, a plug 53, a second wiring layer 24, and a pad 25 are formed on the silicon filler 48 and the contact 71.

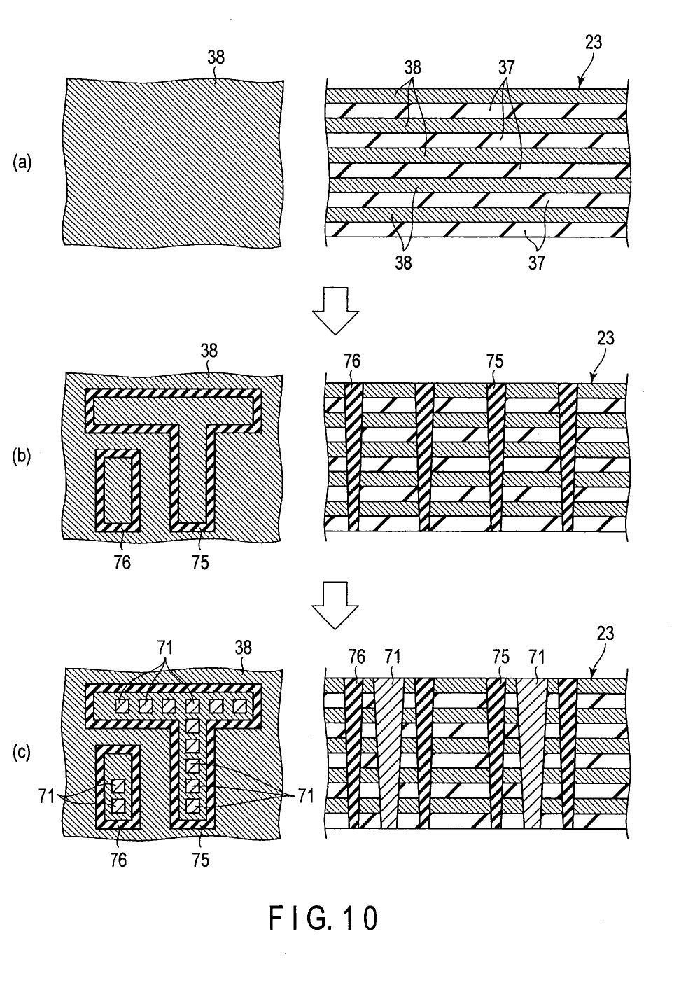

In addition, the insulating portion 75 may be provided before or after the contacts 71 are formed. FIG. 10 is a cross-sectional diagram illustrating an example of a method of forming the peripheral portion of the conductor part. As illustrated in FIG. 10, for example, the insulating portion 75 is provided first in the lamination structure 23, and then the contact 71 is provided.

Next, advantages of the semiconductor device 1 according to the embodiment will be described.

For comparison, an example of another method of manufacturing the semiconductor device is described. In this manufacturing method, the memory holes and the contact holes are opened in different processes. More specifically, after the memory hole is formed and the silicon filler is provided inside thereof, a large through-hole is provided at the site where the contact is to be provided. The through-hole is formed with a diameter larger than that of the contact.

Next, the through-hole is backfilled with an insulating material at one time. Next, the contact hole is provided in the insulating material, and the contact is provided inside thereof. Therefore, the contact insulated from the conductor layer of the lamination structure is provided in the inner portion of the through-hole.

However, in this manufacturing method, it is difficult to perform planarization polishing on a pattern of the peripheral portion and a pattern of the cell portion, causing a step therebetween is enlarged. In addition, in the peripheral portion, since the deep, large through-hole is filled with the insulating material at one time, good planarization may not be implemented. Namely, since the area of the opening of the through-hole is large, the surface thereof may be recessed when the through-hole is filled with the insulating material. In addition, when the deep, large through-hole is filled with the insulating material, holes may exist inside the through-hole.

Therefore, due to the above-described manufacturing method, metal residues may exist in the vicinity of the contact. The metal residues may cause defects such as short-circuit.

In addition, in the semiconductor device according to the manufacturing method, for example, a large area of the opening of the through-hole needs to be secured in order to prevent holes being generated. Therefore, it is difficult to implement reduction in chip size. In addition, in the case where a plurality of the through-holes is provided, it is difficult to decease a distance between the through-holes less than, for example, 6 μm. In addition, it is difficult to decease a distance between the inner surface of the through-hole and the contact less than, for example, 0.5 μm.

In the semiconductor device 1 according to the embodiment, the contact hole 72 is opened by using the same mask 81 as that of the memory hole 44. Therefore, the process of separately opening the through-hole in the peripheral portion 12 can be omitted, and the planarization process (e.g., planarization polishing) for the cell portion 11 and the peripheral portion 12 can be performed at one time.

Therefore, the number of planarization processes can be reduced, and a step cannot easily occur between the cell portion 11 and the peripheral portion 12. Therefore, the metal residues cannot easily exist in the vicinity of the contact, so that it is possible to suppress the occurrence of defects of the semiconductor device 1. Therefore, according to the embodiment, it is possible to provide a semiconductor device 1 of which reliability is improved.

In addition, in the manufacturing method according to the embodiment, the process of burying the deep, large through-hole with the insulating material may not be performed. Therefore, it is possible to prevent recesses or holes from being generated in the surface accompanying with the burying of the deep, large through-hole with the insulating material. Therefore, the metal residues cannot easily exist in the vicinity of the contact, so that it is possible to suppress the occurrence of defects of the semiconductor device 1.

In the embodiment, the contact 71 is connected to the conductive layer 38 of the lamination structure 23 at the inner side of the insulating portion 75. Accordingly, the contact 71 may use the conductive layer 38 at the inner side of the insulating film 75 as a portion of the wiring. Therefore, the area required for layout of wirings is decreased, so that reduction in chip size can be implemented.

In the embodiment, the insulating portion 75 integrally surrounds the plurality of contacts 71. A plurality of the contacts 71 is connected to each other through the conductive layers 38 at the inner side of the insulating portion 75. According to the configuration, the plurality of contacts 71 can be used as conductive paths having the same potential with each other, so that wiring resistance can be reduced.

In the embodiment, the plurality of contacts 71 includes a first contact 71A and a second contact 71B connected to the first contact 71A through the conductive layer 38. The first wiring layer 22 is configured to include a metal wiring 33 connected to the first contact 71A. The second wiring layer 24 is configured to include another metal wiring 64 connected to the second contact 71B. According to the configuration, there is no need for the metal wiring 33 of the first wiring layer 22 to be directly connected to the second contact 71B. Therefore, a degree of freedom in layout of the metal wiring 33 of the first wiring layer 22 and the metal wiring 64 of the second wiring layer 24 is improved. This contributes to reduction in chip size.

In the embodiment, the plurality of contacts 71 includes a first contact 71C and a second contact 71D which are classified according to a point of view different from the above-described point of view. The second wiring layer 24 is configured to include a first metal wiring 64 and a second metal wiring 65. The first metal wiring 64, a projection of the metal wiring overlapping the first contact 71C in the thickness direction of the lamination structure 23 and is connected to the first contact 71C. The second metal wiring 65, a projection of the metal wiring overlapping the second contact 71D in the thickness direction of the lamination structure 23 and is insulated from the second contact 71D.

Namely, in the configuration of the embodiment, the plurality of contacts 71C and the plurality of contacts 71D are connected to each other through the conductive layer 38. Accordingly, another metal wiring 65 which is not connected to the contact 71D can be arranged by using an upper (or lower) space of some contact (e.g., the second contact 71D). Therefore, a degree of freedom in layout of wirings is improved, so that reduction in chip size is further implemented.

In the embodiment, a plurality the contacts 71 is connected to the metal wiring 33 of the first wiring layer 22. Therefore, mesh-shaped conductive paths are formed by the first wiring layer 22, the plurality of contacts 71, and a plurality of the conductive layers 38. According to the configuration, wiring resistance can be further reduced.

In the embodiment, the conductive layer 38 of the lamination structure 23 remains in the vicinity of the contact 71. Therefore, a covering ratio (i.e., a ratio of area where the conductive layer 38 exists) of the peripheral portion 12 can approach the covering ratio of the cell portion 11. If the ratios approach each other, the following process can be performed while the peripheral portion 12 and the cell portion 11 are treated to be almost the same. This contributes to improvement of productivity of the semiconductor part 5.

As illustrated in FIG. 4, in the embodiment, a distance L1 between a plurality of the insulating films 75b can be reduced down to, for example, several tens of nanometers. In addition, a distance L2 between the insulating film 75b and the contact 71 can be reduced down to, for example, several tens of nanometers. Therefore, in the semiconductor device 1 according to the embodiment, reduction in chip size can be implemented in comparison to a semiconductor device having deep, large through-holes.

In addition, the present invention is not limited to the configuration where the plurality of contacts 71 is collectively surrounded by the insulating layer 75 or the insulating layer 76. The plurality of contacts 71 may be individually surrounded by the insulating layer 75 or the insulating layer 76. Namely, the plurality of contacts 71 may not be connected to each other.

Next, semiconductor devices 1 according to a second embodiment and a third embodiments will be described. The components having functions which are the same as or similar to those of the first embodiment are denoted by the same reference numerals, and the description thereof is omitted. In addition, the configurations which are not described below are the same as those of the first embodiment.

### Second Embodiment

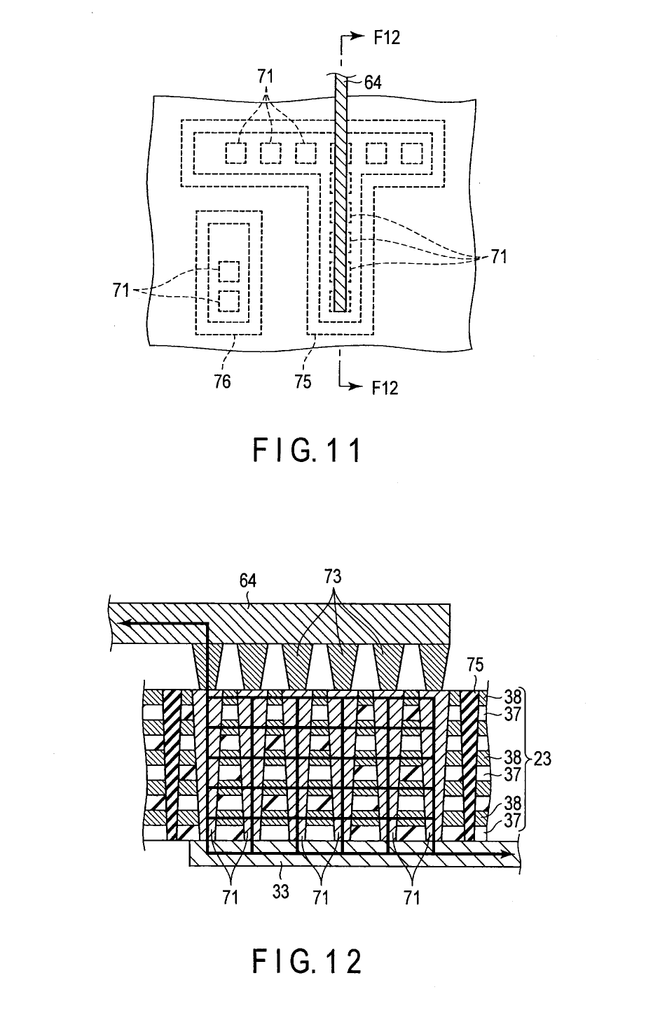

FIGS. 11 and 12 illustrate a semiconductor device 1 according to a second embodiment. As illustrated in FIGS. 11 and 12, in the embodiment, each of the contacts 71 are connected to a metal wiring 64 of the second wiring layer 24 through a plurality of contacts 73 in the upper portion.

According to the configuration, the same effects as those of the first embodiment can be obtained. In addition, according to the embodiment, and wiring resistance including connections between the second wiring layer 24 and the plurality of contacts 71 can be further reduced.

### Third Embodiment

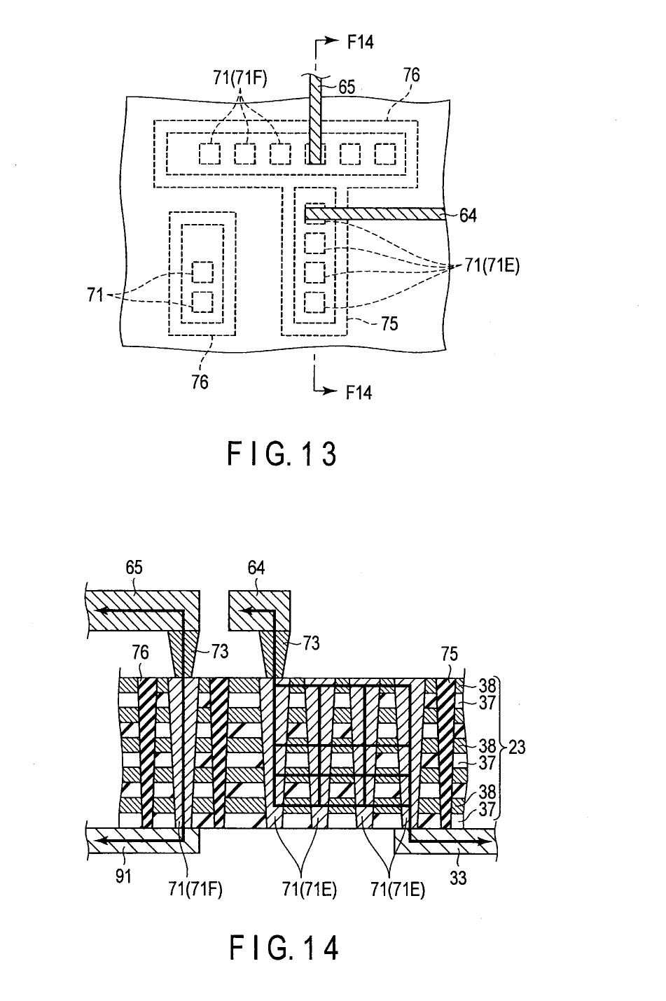

FIGS. 13 and 14 illustrate a semiconductor device 1 according to a third embodiment. As illustrated in FIGS. 13 and 14, in the embodiment, the semiconductor device 1 is configured to include an insulating portion 76 (i.e., a second insulating portion) which penetrates at least a portion of the lamination structure 23.

The insulating portion 76 surrounds the contacts 71 (or the contact holes 72) and extends in the Z direction. In the embodiment, the insulating portion 76 (or the insulating film 76b) penetrates the conductive layer 41, the insulating layer 40, and the lamination structure 23 in the Z direction to reach the conductive layer 34. The insulating film 76b of the insulating portion 76 is formed with, for example, a silicon oxide film. The insulating film 76b is formed in the same process as that for the insulating film 75b (e.g., substantially simultaneously).

As illustrated in FIGS. 13 and 14, the first wiring layer 22 is configured to include a first metal wiring 33 and a second metal wiring 91. The first metal wiring 33 and the second metal wiring 91 has the divided potentials, and different signals or currents flow through the first metal wiring 33 and the second metal wiring 91. The plurality of contacts 71 is further classified according to a point of view different from the above-described point of view. The first metal wiring 33 includes a first contact 71E and a second contact 71F.

The first contact 71E is connected to the first metal wiring 33. The second contact 71F is connected to the second metal wiring 91. In addition, the second wiring layer 24 includes a third metal wiring 64 connected to the first contact 71E and a fourth metal wiring 65 connected to the second contact 71F.

As illustrated in FIGS. 13 and 14, the first insulating portion 75 (or the first insulating film 75b) surrounds the first contact 71. The second insulating portion 76 (or the second insulating film 76b) surrounds the second contact 71F so as to be insulated from the first contact 71E.

According to the configuration, the same effects as those of the first embodiment can be obtained. In addition, according to the embodiment, the first insulating portion 75 and the second insulating portion 76 are selectively provided according to potential relation of the contacts 71, so that the first contact 71E and the second contact 71F can be insulated from each other. Therefore, the plurality of contacts 71 can be used as different wiring paths, so that a degree of freedom in layout of wirings can be improved.

### Fourth Embodiment

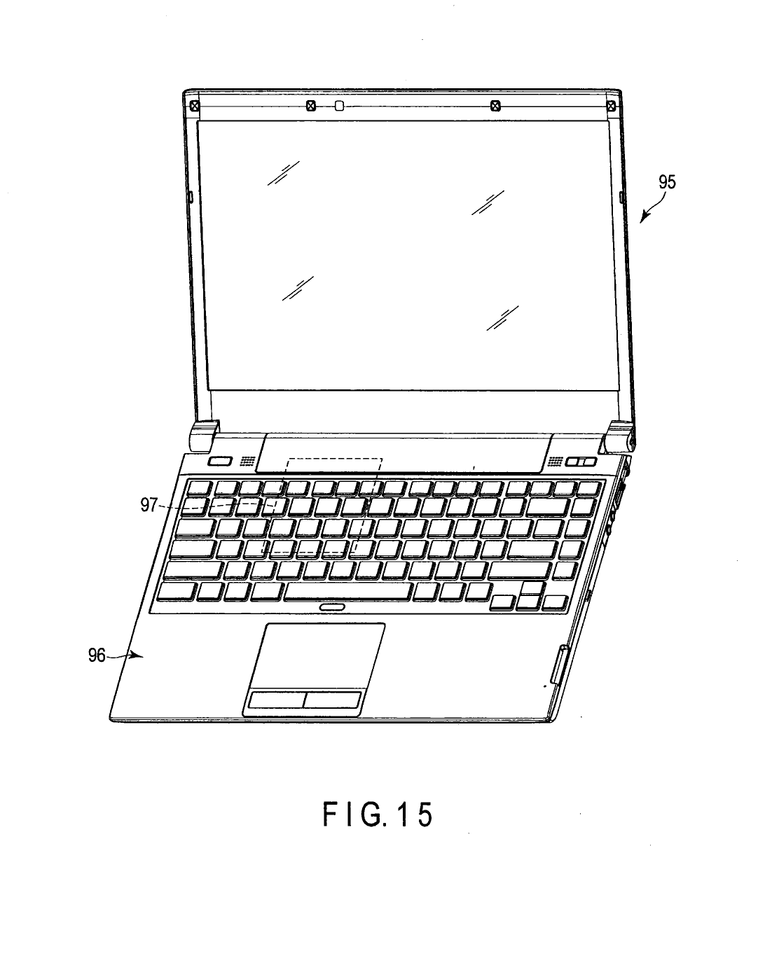

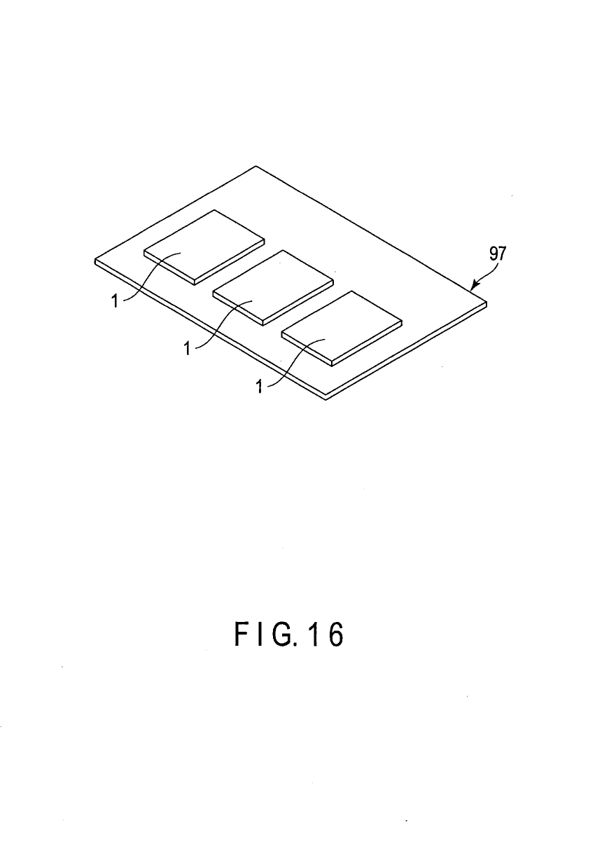

FIGS. 15 and 16 illustrate an electronic apparatus 95 (e.g., an information processing apparatus) according to a fourth embodiment. The electronic apparatus 95 according to the embodiment is, for example, a portable computer. However, the electronic apparatus 95 may be a tablet terminal, a digital camera, a video camera, a server connected to a network, or the like.

The electronic apparatus 95 is configured to include a case 96 and a circuit board 97 accommodated in the case 96. A semiconductor device 1 is mounted to a circuit board 97. The semiconductor device 1 is connected to the circuit board 97. The semiconductor device 1 may be any one of the semiconductor devices 1 according to the first to fourth embodiments or may be configured with only the semiconductor part 5.

A configuration of the memory cell array is mentioned, for example, in U.S. patent application Ser. No. 12/407,403 filed on Mar. 19, 2009 and entitled “THREE DIMENSIONAL STACKED NONVOLATILE SEMICONDUCTOR MEMORY.” Further, such a configuration is mentioned in U.S. patent application Ser. No. 12/406,524 filed on Mar. 18, 2009 and entitled “THREE DIMENSIONAL STACKED NONVOLATILE SEMICONDUCTOR MEMORY,” U.S. patent application Ser. No. 12/679, 991 filed on Mar. 25, 2010 and entitled “NON-VOLATILE SEMICONDUCTOR MEMORY DEVICE AND METHOD OF MANUFACTURING THE SAME,” and U.S. patent application Ser. No. 12/532,030 filed on Mar. 23, 2009 and entitled “SEMICONDUCTOR MEMORY AND METHOD FOR MANUFACTURING SAME.” The entire contents of these patent applications are incorporated herein by reference.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising a cell portion and a peripheral portion, comprising:
a substrate;
a first insulating layer disposed on the substrate;
a first conductive layer disposed on the first insulating layer;
a second insulating layer disposed on the first conductive layer;
a second conductive layer disposed on the second insulating layer;
a first wiring layer disposed between the first insulating layer and the substrate;
a second wiring layer disposed above the second conductive layer;
a third insulating film disposed in the peripheral portion, the third insulating film being extending in a first direction perpendicular to the substrate; and
a contact disposed in an area surrounded by the third insulating film, the contact being connected to the first wiring layer and the second wiring layer.

2. The device of claim 1, further comprising
a plurality of contacts including the contact,
wherein the contacts are connected to each other through the first conductive layer or the second conductive layer in the area.

3. The device of claim 2,
wherein the contacts include a first contact and a second contact which is connected to the first contact,
wherein the first wiring layer is configured to include a metal wiring which is connected to the first contact, and
wherein the second wiring layer is configured to include another metal wiring which is connected to the second contact.

4. The device of claim 2,
wherein the contacts include a first contact and a second contact which is connected to the first contact, and
wherein the second wiring layer is configured to include a metal wiring, a projection of the metal wiring overlapping the first contact and is connected to the first contact and another metal wiring, a projection of the metal wiring overlapping the second contact and is insulated from the second contact.

5. The device of claim 2, wherein the plurality of the contacts are connected to the first wiring layer, and mesh-shaped conductive paths are provided with the first wiring layer, the contacts, and the layers.

6. The device of claim 1, further comprising:
a plurality of contacts including the contact; and
a fourth insulating film is extending in the first insulating layer, the first conductive layer, the second insulating layer, and the second conductive layer in the first direction,
wherein the contacts include a first contact and a second contact, and
wherein the first contact disposed in the area surrounded by the third insulating film, and the second contact disposed in an area surrounded by the forth insulating film so as to be insulated from the first contact.

7. A semiconductor device comprising:
a substrate in which a transistor is provided;
a first insulating layer disposed on the substrate;
a first conductive layer disposed on the first insulating layer;
a second insulating layer disposed on the first conductive layer;
a second conductive layer disposed on the second insulating layer;
a third insulating film being extending in a first direction perpendicular to the substrate; and
a contact disposed in an area surrounded by the third insulating film, the contact being connected the substrate.

8. The device of claim 7, further comprising a plurality of contacts including the contact,
wherein the contacts are connected to each other through the first conductive layer or the second conductive layer in the area.

9. The device of claim 8, further comprising:
a first wiring layer disposed between the first insulating layer and the substrate;
a second wiring layer disposed above the second conductive layer;
wherein the first wiring layer is configured to include a metal wiring which is connected to the first contact, and
wherein the second wiring layer is configured to include another metal wiring which is connected to the second contact.

10. The device of claim 8, further comprising:
a first wiring layer disposed between the first insulating layer and the substrate;
a second wiring layer disposed above the second conductive layer;
wherein the contacts include a first contact and a second contact which is connected to the first contact, and
wherein the second wiring layer is configured to include a metal wiring, a projection of the metal wiring overlapping the first contact and is connected to the first contact and another metal wiring, a projection of the metal wiring overlapping the second contact and is insulated from the second contact.

11. The device of claim 8, further comprising:
a wiring layer disposed between the first insulating layer and the substrate,
wherein the plurality of the contacts are connected to the first wiring layer, and mesh-shaped conductive paths are provided with the first wiring layer, the contacts, and the layers.

12. The device of claim 7, further comprising:
a plurality of contacts including the contact; and
a fourth insulating film is extending in the first insulating layer, the first conductive layer, the second insulating layer, and the second conductive layer in the first direction,
wherein the contacts include a first contact and a second contact, and
wherein the first contact disposed in the area surrounded by the third insulating film, and the second contact disposed in an area surrounded by the forth insulating film so as to be insulated from the first contact.

13. The device of claim 7, further comprising:
a memory hole which is extending the first insulating layer, the first conductive layer, the second insulating layer, and the second conductive layer and in which the memory film is provided, and
a contact hole which is extending the the first insulating layer, the first conductive layer, the second insulating layer, and the second conductive layer and in which the contact is provided, and
wherein the contact hole is opened by using the same mask as that for the memory hole.

14. An electronic apparatus comprising:
a case;
a circuit board which is accommodated in the case; and
a semiconductor device, which is mounted on the circuit board, including a substrate in which a transistor is provided, a lamination structure where a memory hole and a contact hole are opened by using the same mask, and a contact provided in the contact hole to be connected to the transistor.
